(19) United States
(12) Patent Application Publication
(10) Pub. No.: US 2009/0066345 A1
(43) Pub. Date: Mar. 12, 2009

(54) SENSOR HAVING ORGANIC FIELD EFFECT TRANSISTORS

(75) Inventors: Hagen Klauk, Stuttgart (DE); Marcus Halik, Erlangen (DE); Ute Zschieschang, Stuttgart (DE); Guenter Schmid, Hemhofen (DE); Grzegorz Darlinski, Aachen (DE); Rainer Waser, Aachen (DE); Ralf Brederlow, Poing (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 10/599,470

(22) PCT Filed: Mar. 30, 2005
(86) PCT No.: PCT/DE2005/000559

§ 371 Date: Nov. 17, 2008

(30) Foreign Application Priority Data
Apr. 1, 2004 (DE) 10 2004 016 155.0

(51) Int. Cl. G01R 27/26; H01L 51/05

(52) U.S. Cl. 324/661; 257/40; 257/E51.005

(57) ABSTRACT

A force sensor based on an organic field effect transistor applied on a substrate is disclosed. In one embodiment, a mechanical force acting on the transistor causes a change in its source-drain voltage or its source-drain current which corresponds to said force and which can in each case be detected as measurement quantity for the acting force, a diaphragm-based pressure sensor that uses a force sensor of this type, a one- or two-dimensional position sensor that uses a multiplicity of force sensors of this type, and a fingerprint sensor that uses a multiplicity of such force sensors.

### BACKGROUND

The invention relates to a force sensor having organic field effect transistors, a pressure sensor, a position sensor and also a fingerprint sensor all based on organic field effect transistors.

The qualitative detection or quantitative measurement of mechanical forces such as occur upon a human touch or upon contact with solid objects, is in practice usually effected by the use of force sensors which are generally based either on the piezoelectric, resistive or capacitive operative principle:

In a piezoelectric force sensor, an electrical charge proportional to the active force is generated by the mechanical deformation of a crystal constructed from quartz or a special piezoceramic at the external areas of the crystal. The electrical energy generated in the process is very low, so that a charge amplifier having a high input resistance is required for evaluation purposes.

In a resistive force sensor, a film coated with an electrically conductive polymer is pressed against a metal contact structure by the acting force, with the result that the electrical resistance measured between the metal contacts decreases measurably. On account of the properties of the polymer layer, the change in the resistance, over a relatively wide range, depends proportionally on the acting mechanical force. Film force sensors are used for example in keyboards or for electronic signature detection.

In a capacitive force sensor, an insulator layer situated between two electrically conductive areas is compressed by the acting force, the capacitance of the arrangement increasing at the location of the acting force. However, the change in capacitance is relatively small.

WO 03/079,449 A1 (cf., in particular, FIG. 5 with the associated description on pages 10 and 11) describes a force sensor that is also used as a fingerprint sensor and a two-dimensional position sensor. The structure shown in FIG. 5 has a sensor array above a pixel array having a multiplicity of LEDs, which sensor array comprises a compressible layer made of dielectric or very high-resistance material inserted between a transparent top electrode layer, having. e.g., ITO, and an underlying conductive barrier material and also an insulating levelling layer. As soon as a pressure is exerted on this material stack, the distance between the electrode layer and the conductive barrier material changes, thereby establishing a measurable change in capacitance over the dielectric material or a reduction of the resistance over the very high-resistance material.

For these and other reasons, there is a need for the present invention.

### SUMMARY

One embodiment provides a force sensor having a substrate and an organic field effect transistor applied on the substrate, in which a mechanical force acting on the transistor causes a change in its source-drain voltage or its source-drain current which corresponds to the force and is detected as measurement quantity for the acting force.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 schematically illustrates in cross section a pentacene transistor that preferably serves as organic field effect transistor used in the invention.

FIGS. 2A and 2B illustrate two alternative circuit variants which utilize the reproducible reversible dependence of the drain current of a pentacene transistor in accordance with FIG. 1 on the mechanical force acting on the transistor and serving for generating an electrical measurement signal.

FIG. 3. graphically illustrates the measured dependence of the drain current of a pentacene transistor integrated on a glass substrate on the gate-source voltage in each case when no force is exerted on the pentacene transistor and when a mechanical force acts on the transistor by means of a pin that can be lowered in controlled fashion.

FIG. 4 graphically illustrates, on the basis of the measurement results from FIG. 3, the difference between low and high states and also the percentage change in the drain current as a function of the gate-source voltage.

FIG. 5 schematically illustrates an application of the force sensor according to the invention as a diaphragm-based pressure sensor.

FIG. 6 graphically illustrates the measured dependence of the drain current of a pentacene transistor integrated on a PEN diaphragm in accordance with FIG. 5 on the bending of the PEN diaphragm.

FIG. 7 schematically illustrates a circuit arrangement of a one-dimensional position sensor using a plurality of force sensors according to the invention.

FIG. 8 schematically illustrates a circuit arrangement of a two-dimensional position sensor using a two-dimensional matrix of a multiplicity of force sensors according to the invention.

FIGS. 9 to 11 illustrate schematic cross sections of three exemplary embodiments of fingerprint sensors according to the invention which use the force sensor according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment of the invention provides a force sensor which can be used diversely and can be produced cost-effectively and in which the acting force can be converted into a reproducible measurement current that is reversible after the end of the force action, or a measurement voltage.

Another embodiment of the invention consists in specifying a pressure sensor using at least one force sensor of this type. Another embodiment of the invention consists in specifying a one- or two-dimensional position sensor using a force sensor of this type. Another embodiment consists in providing a fingerprint sensor using a force sensor of this type.

The production of suitable pentacene transistors on various substrates is described in the following documents:
M. Halik et al.; “Polymer gate dielectrics and conducting-polymer contacts for high-performance organic thin film transistors” in Advanced Materials, vol. 14, p. 1717 (2002); H. Klauk et al.: “High-mobility polymer gate dielectric pentacene thin film transistors” in Journal of Applied Physics, vol. 92, p. 5259 (2002), and
H. Klauk et al: “Pentacene organic transistors and ring oscillators on glass and on flexible polymeric substrates” in Applied Physics Letters, vol. 82, p. 4175 (2003).

In accordance with a first aspect of the invention, the first component object is achieved by means of a force sensor based on an organic field effect transistor applied on a substrate, in which a mechanical force acting on the transistor causes a change in its source-drain voltage or its source-drain current which corresponds to the force and which can in each case be detected as measurement quantity for the acting force.

The organic field effect transistor is preferably a pentacene transistor having an active layer made of pentacene between a drain electrode and a source electrode. Consequently, the force sensor according to the invention utilizes the reproducible reversible dependence of the drain current of an organic field effect transistor on the mechanical force acting on the transistor. Since organic field effect transistors can be integrated particularly simply and cost-effectively on arbitrary substrates, organic field effect transistors of this type are particularly well suited to the realization of force sensors.

The aforementioned substrate on which the organic field effect transistor, in particular the pentacene transistor, is applied may include for example glass, ceramic, plastic, a polymer film, metal film or paper. In the case where the substrate includes a polymer film, preference is to be given in particular to polyethylene naphthalate (PEN), polyethylene terephthalate (PET) polyimide (PI), polycarbonate and/or polyethene ether ketones (PEEK).

In one possible circuit example of a force sensor of this type, the electrical measurement quantity is the drain-source voltage of the organic field effect transistor. In this case, a constant gate-source voltage and a constant drain current are applied to the transistor at the measurement instant and the drain-source voltage is tapped off as measurement quantity for the acting force.

In another circuit example of a force sensor of this type, the electrical measurement quantity is the drain current of the organic field effect transistor. In this circuit principle, a constant gate-source voltage and a constant drain-source voltage are applied to the organic field effect transistor at the measurement instant.

By virtue of the wide range of substrate materials described above, force sensors for different types of applications and for different measurement ranges which all have the same basic construction can be realized in a simple and cost-effective manner.

One of the applications is a pressure sensor according to the invention, having a least one force sensor according to the invention on a substrate configured as a diaphragm. In this case, the electrical measurement quantity (the latter, as explained above, is either the drain current or the drain-source voltage) corresponds to the bending state of the diaphragm at the respective location of the at least one force sensor.

Known integrated pressure sensors for measuring the static and/or dynamic pressure in liquid or gaseous media are generally based on the principle of an elastic structure that deforms under pressure (the diaphragm), one or a plurality of pressure transducers (sensors) being integrated on the surface thereof. In this case, the pressure to be measured acts against one area of the diaphragm, while a constant reference pressure set with the aid of a sealed volume (or a volume open to the atmosphere) acts on the other diaphragm area. Generally, either a resistive or a capacitive operative principle is utilized for the pressure conversion at the diaphragm, that is to say that the elastic mechanical deformation of the diaphragm leads to a measurable alteration either of an electrical resistance or of an electrical capacitance. In this case, resistive pressure sensors (strain gauges) are based either on the evaluation of the change in resistance in metallic conductor tracks (change in resistance on account of the alteration of the geometrical cross section of the conductor track) or on the piezoresistive effect in a semiconductor structure.

The fundamental disadvantage of metallic strain gauges is the low sensitivity since the relative resistance change to be measured is very small. Piezoresistive pressure transducers have the disadvantage that they are comparatively complicated and expensive to produce on account of the necessity of processing silicon substrates. Moreover, the resistance and the change in resistance in the semiconductor are greatly dependent on temperature. A further disadvantage is the fact that piezoresistive pressure sensors are suitable only for the measurement of pressures in gaseous and liquid media since direct contact with a solid object would lead to destruction of the extremely thin silicon diaphragm.

The pressure sensor according to the invention utilizes the reproducible, reversible dependence of the threshold voltage of organic field effect transistors on the bending state of the substrate. Consequently, the invention proposes an integrated pressure sensor which is based on a deformable diaphragm and in which the pressure conversion is based on the measurable alteration—dependent on the bending state of the diaphragm—of the threshold voltage of one or more organic field effect transistors integrated on the diaphragm (the threshold voltage is defined as that input voltage of the transistor at which the output current of the transistor increases abruptly on account of the accumulation in a charge carrier channel). Due to the availability outlined above of a multiplicity of commercially available inexpensive flexible diaphragm materials, by means of targeted optimization of the thickness and the surface of the diaphragm, it is possible, in a simple manner, to realize a pressure sensor for different applications and different measurement ranges in each case based on the same fundamental construction. In particular, this permits not only the measurement of pressures in gaseous and liquid media, but also the measurement of forces and pressures which are exerted on the diaphragm by solid objects. This is an important advantage over conventional piezoresistive sensors.

A further application according to the invention of the force sensor according to the invention is a one- or two-dimensional position sensor for measuring the position of a mechanical force action along a line or within an area using a multiplicity of force sensors according to the invention which are in each case based on an organic field effect transistor and are arranged at regular distances from one another in the form of a one- or two-dimensional matrix on a common substrate.

In hitherto conventional one- or two-dimensional position sensors, a predetermined number of force sensors which are generally based either on the resistive or the capacitive operative principle have been arranged along a line or within a two-dimensional area. In a resistive position sensor, a film coated with an electrically conductive polymer is pressed against a metal contact structure by the acting force, so that the electrical resistance measured between the metal contacts decreases measurably. On account of the properties of the polymer layer, the change in the resistance, over a relatively wide range, depends proportionally on the acting mechanical force. In a capacitive position sensor, an insulator layer situated between two electrically conductive areas is compressed by the acting force, a capacitance of the arrangement increasing. However, the change in capacitance is extremely small.

By contrast, the position sensor according to the invention utilizes the reproducible reversible dependence of the drain current of organic field effect transistors on the mechanical force acting on the respective transistor.

In a two-dimensional position sensor of the invention described as an exemplary embodiment, the measurement data are detected row by row by selection of all the organic field effect transistors within a row by application of a corresponding gate-source voltage by means of a row decoder. The gate-source voltage is chosen such that the transistors in the row are switched on; at the same time, all the other rows of the matrix are deselected by application of a corresponding gate-source voltage by the row decoder, so that the transistors in these rows are turned off and make no contribution to the measurement current. The deselect voltage is chosen such that the transistors turn off. The measurement voltages dependent on the acting mechanical force, that is to say the drain-source voltages of the individual transistors within the selected row are detected after activation of the constant-current sources by a driving and measuring unit connected to the columns of the matrix.

A further application of the force sensor according to the invention is a fingerprint sensor according to the invention, which utilizes the reproducible, reversible dependence of the drain current of organic field effect transistors arranged in matrix form on the mechanical force acting on the transistors.

The fingerprint is usually identified by the fingertip touching a two-dimensional arrangement (matrix) of individual sensors, with the aid of which the microscopic topography of the fingertip is detected point by point. For identification of the fingerprint, in each of the individual sensors the characteristic physical quantity (mechanical pressure or electrical conductivity) is converted into an electrical quantity, voltage, current intensity or capacitance, which can be detected by the system, thereby enabling an electronic detection and evaluation of the measurement results provided by the individual sensors. Capacitive, piezoelectric or resistance effects are optionally utilized for the conversion of the physical quantity into an electrical quantity.

Due to the nature of the object to be examined, a series of problems which are usually independent of the type of effect utilized in the sensor arise in conventional fingerprint sensor technology. These problems are caused by the chemical composition of human perspiration and the resultant contamination and corrosion phenomena principally of the electrical connections in and between the individual sensors but also of the active sensor material.

An inexpensive pressure sensor that is based on organic field effect transistors is proposed with the fingerprint sensor according to the invention. In the case of this fingerprint sensor, sufficient resistance towards aggressive substances, in particular human perspiration, can be ensured by a suitable choice of protective layers.

The sensor system of the fingerprint sensor according to the invention includes a two-dimensional matrix of organic field effect transistors with driving and measuring unit and row decoder of the kind already described above for a two-dimensional position sensor.

The protection of the sensor array against environmental contamination that is primarily caused by human perspiration and adversely affects the longevity of such a sensor is effected by applying a one- or two-layered protective layer to the sensor array.

This invention describes a force sensor in which the force conversion is based on the measurable alteration of the drain current of an organic field effect transistor, the alteration being dependent on the magnitude of the acting force. Besides the dependence of the drain current on the electrical potentials present at the drain electrode and at the gate electrode of an organic field effect transistor, in these transistors the drain current additionally depends on the mechanical force acting on the transistor. Since organic transistors can be integrated particularly simply and cost-effectively on arbitrary substrates, they are particularly well suited to the realization of force sensors.

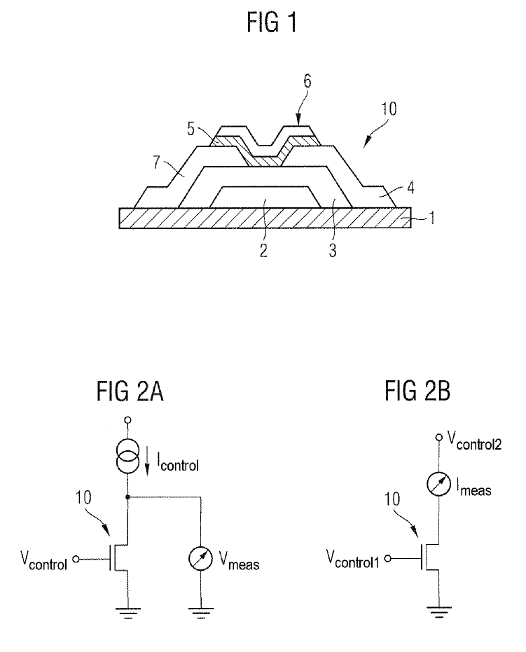

The invention prefers, for the organic field effect transistor, a pentacene transistor illustrated in cross section in FIG. 1. Instead of using pentacene for the active layer 5, it is also possible to use for example thiophene, oligothiophene and polythiophene and fluorene for the material of the active layer 5. The pentacene transistor 10 illustrated in FIG. 1 is applied to a substrate 1 and has a gate electrode 2, a PVP gate dielectric 3, a drain electrode 4, an active pentacene layer 5, a passivation layer 6 and a source electrode 7.

A wide range of materials are appropriate for the material of the substrate, such as, for example, glass, ceramic, plastic, polymer film, metal film and paper. Polyethylene naphthalate (PEN), polyethylene terephthalate (PET), polyimide (PI), polycarbonate, polyethene ether ketones (PEEK) are appropriate from among the polymer films. By virtue of this wide range of substrate materials, it is possible, in a simple manner, to realise force sensors in particular for the different applications described further below and for different measurement ranges, based on the same fundamental construction.

FIGS. 2A and 2B illustrate two circuit variants for force sensor elements based on organic transistors. FIG. 2A illustrates a circuit arrangement for the driving of the sensor, in particular of the pentacene transistor 10 illustrated in FIG. 1, by means of a constant current source I_{control} and the measurement of the drain-source voltage of the transistor as measurement quantity Vₘₑₐₛ. Given a constant drain current I_{control} and a constant gate-source voltage V_{control}, the measured voltage Vₘₑₐₛ depends only on the acting mechanical force and thus permits the force acting on the pentacene transistor to be determined. In this case, the mechanical force, depending on the respective application (see further below), may act for example from above on the passivation layer 6 or by way of a deformation, e.g., bending of the substrate 1 carrying the pentacene transistor.

FIG. 2B illustrates the driving of the force sensor 10 by means of a constant gate-source voltage V_{control1} and a constant drain-source voltage V_{control2} and the measurement of the drain current of the pentacene transistor 10 as measurement quantity Iₘₑₐₛ. In the case of the circuit arrangement illustrated in FIG. 2, the measured current Iₘₑₐₛ permits a conclusion to be drawn about the force acting on the transistor.

The two circuit variants illustrated in FIGS. 2A and 2B are equivalent with regard to the electrical mode of operation.

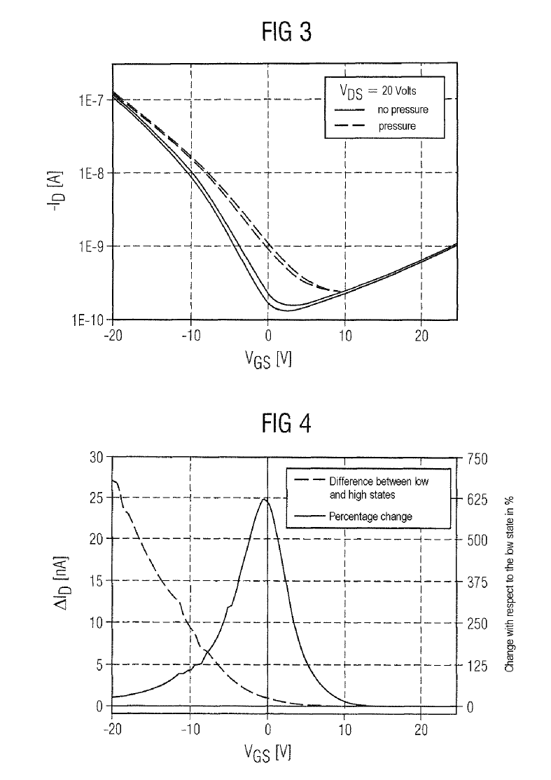

On the basis of the circuit variant of a force sensor according to the invention as illustrated in FIG. 2B, FIG. 3 graphically illustrates measured values of the drain current I_{D} (in amperes), which corresponds to the measurement quantity Iₘₑₐₛ, as a function of the gate-source voltage V_{GS} measured in volts, to be precise depicted by solid lines in the pressure-free state, that is to say when no force acts on the force sensor, and depicted by dashed lines when a mechanical force is exerted on the force sensor by means of a pin that can be lowered in controlled fashion. The drain-source voltage V_{DS} was constant and equal to 20 V in this case. The differences illustrated in FIG. 3 between the drain current without a force action (solid line) and the drain current with a force acting on the pentacene transistor (dashed lines) result in difference values ΔI_{D} of the drain current (according to the dashed curve in FIG. 4) of approximately between 0 and 27 nA in the on-state range of the pentacene transistor 10, and if the operating point of the pentacene transistor 10 is put into the on-state range of the transistor 10 by means of the choice of the gate-source voltage V_{GS}, a considerable percentage change in the high state (force acts on the pentacene transistor) with respect to the low state (no force acts on the pentacene transistor 10) is ascertained, as represented by the solid curve in FIG. 4.

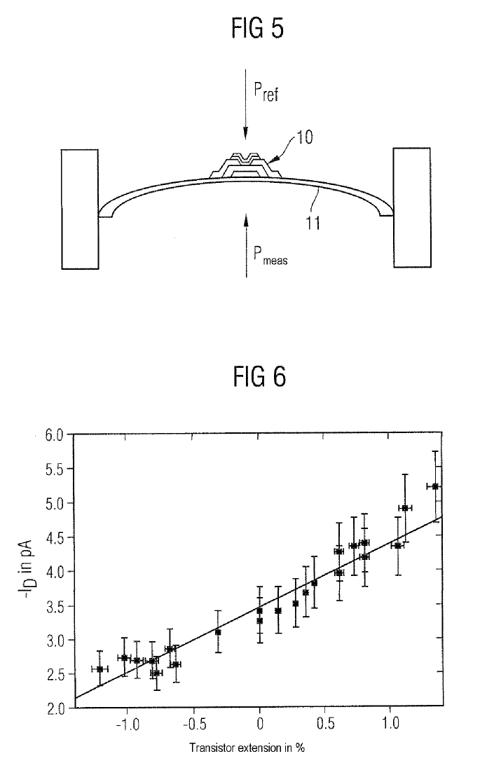

Furthermore, an integrated pressure sensor based on a deformable diaphragm 11 is described with reference to FIGS. 5 and 6, in which sensor the pressure conversion is based on a measurable alteration—dependent on the bending state of the diaphragm—of the threshold voltage of one or more organic field effect transistors, in particular pentacene transistors 10, integrated on the diaphragm. In this case, the threshold voltage is defined as that input voltage of the transistor at which the output current of the transistor increases abruptly on account of the accumulation in a charge carrier channel.

FIG. 5 illustrates a pressure sensor arrangement in which the substrate 1 is configured as a flexible diaphragm 11 in accordance with FIG. 1, which diaphragm is fixedly clamped in at its outer edge and can be deflected upwards and downwards in its central regions. In the example illustrated in FIG. 5, a pressure Pₘₑₐₛ to be measured acts from below and a reference pressure P_{ref} acts from above on the diaphragm 11 and thus on the pentacene transistor 10 serving as pressure sensor.

In principle, the wide range of materials already described above is appropriate for the diaphragm 11.

It goes without saying that instead of one pentacene transistor 10 in a central position, it is also possible to apply a plurality of pentacene transistors 10 (not illustrated) on the diaphragm 11.

The circuit variants described above with reference to FIGS. 2A and 2B and their mode of operation described with reference to FIG. 3 and FIG. 4 can readily also be used for converting the differential pressure between Pₘₑₐₛ and P_{ref} into an electrical voltage or current signal. In accordance with FIG. 2A, given a constant drain current I_{control} and a constant gate-source voltage V_{control}, the measured voltage Vₘₑₐₛ depends only on the bending state of the diaphragm and thus permits the pressure acting on the diaphragm to be determined. In accordance with FIG. 2B, the measured current Iₘₑₐₛ permits a conclusion to be drawn about the bending state of the diaphragm 11.

FIG. 6 graphically illustrates measurement results for the drain current I_{D} in picoamperes as a function of the percentage transistor extension in the case of a pentacene transistor 10 integrated on a PEN diaphragm in accordance with FIG. 5.

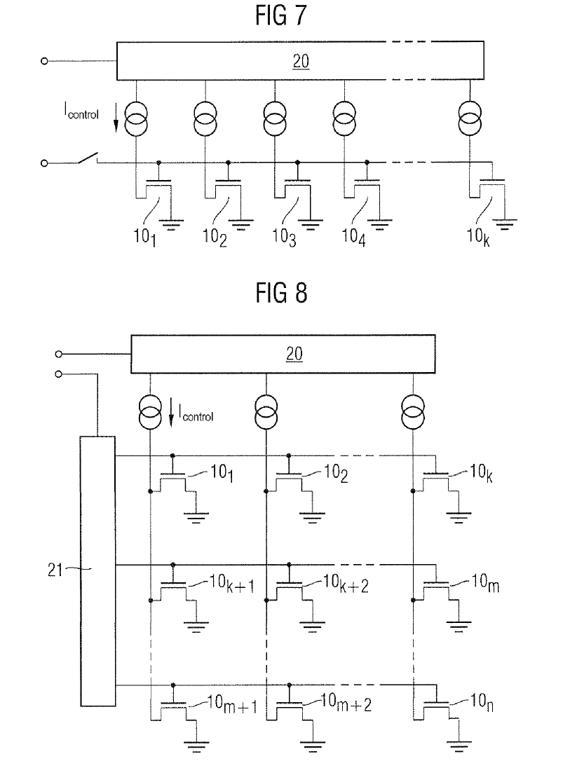

Furthermore, a description is given, with reference to FIGS. 7 and 8, of position sensors which use a multiplicity of force sensors according to the invention and in which the conversion of the physical quantity “force” into a measurable electrical quantity is based on the alteration of the drain current of an organic field effect transistor, in particular pentacene transistor, which alteration is dependent on the acting force.

FIG. 7 illustrates a one-dimensional position sensor that uses a multiplicity of force sensors 10₁, 10₂, 10₃, 10₄, 10_{K} that are spaced apart equidistantly and are arranged along a line. Each of the force sensors is realized in particular by a pentacene transistor 10 such as has been described above with reference to FIGS. 1 to 4. By switching on all the transistors 10₁, 10₂, 10₃, 10₄ 10ₖ within the row by application of a corresponding gate-source voltage and at the same time connecting for example the constant-currant source with the constant current I_{control} as illustrated in FIG. 2A to each of the pentacene transistors 10₁, 10₂, 10₃, . . . , 10ₖ, the respective position of the acting force can be detected by means of the evaluation of the drain-source voltage Vₘₑₐₛ by a driving and measuring unit 20.

FIG. 8 schematically illustrates a two-dimensional arrangement, that is to say a matrix having a multiplicity of organic field effect transistors spaced apart equidistantly, in particular pentacene transistors 10₁, 10₂, . . . , 10ₙ in accordance with FIG. 1, which in interaction with a row decoder 21 and a driving and measuring unit 20 forms a two-dimensional position sensor. Each of the organic field effect transistors, in particular pentacene transistors 10₁, 10₂, . . . , 10ₙ, simultaneously fulfils two tasks: that of a sensor element and that of a switch for addressing the individual pixels within the matrix (selection transistor).

The detection of the measurement data is effected row by row by selection of all the transistors within a row, for example beginning with the transistors 10₁-10ₖ, by application of a corresponding gate-source voltage by means of the row decoder 21. The selection voltage is chosen such that the transistors in the row are switched on. At the same time all the other rows of the matrix are deselected by application of a corresponding gate-source voltage by the row decoder 21, so that the transistors in these non-selected rows are turned off and make no contribution to the measurement current. In this case, the deselect voltage is chosen by the row decoder 21 such that the corresponding transistors of the rows turn off. The measurement voltages dependent on the acting mechanical force, that is to say in accordance with FIG. 2A the drain-source voltages of the transistors within the selected row, are detected after activation of the constant-current sources with the current I_{control} by the driving and measuring unit 20.

The substrate materials mentioned above are in principle also suitable for the one-dimensional position sensor 7 and the two-dimensional position sensor in accordance with FIG. 8. By virtue of this wide range of substrate materials, it is possible, in a simple manner, to realize position sensors for different applications and for different measurement ranges based on the same fundamental construction.

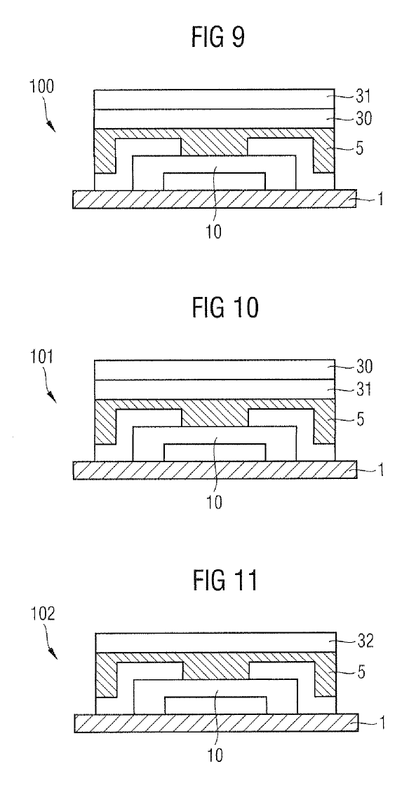

A description is given below with reference to FIGS. 9 to 11, of three different exemplary embodiments of an inexpensive fingerprint sensor configured as a pressure sensor and based on organic field effect transistors, in particular pentacene transistors, in which sufficient robustness towards aggressive substances, in particular human perspiration, is ensured by a suitable choice of protective layers.

The basis of such a fingerprint sensor embodied as a pressure sensor is a two-dimensional sensor array as described above with reference to FIG. 8. The detection of the measurement data is effected row by row by selection of all the transistors within a row by application of a corresponding gate-source voltage by means of the row decoder 21, the selection voltage of which is chosen such that the transistors in the row are switched on. At the same time, the row decoder effects switching-off in other rows of the matrix by application of a corresponding gate-source voltage, that is to say that it deselects these rows, so that the transistors in these rows are turned off and make no contribution to the measurement current. The measurement voltages dependent on the acting mechanical force, that is to say the drain-source voltages of the pentacene transistors within the selected row, are detected after activation of the constant-current sources I_{control} by means of the driving and measuring unit 20.

The protection of the sensor array against environmental contamination caused primarily by human perspiration, which adversely affects the longevity of such a sensor, is effected by applying a one- or two-layered protective layer to the sensor array. Human perspiration is an acidic aqueous solution having a pH of 4.5 that is aggressive to many chemical compounds. Perspiration includes 98% water with the secondary constituents sodium chloride, calcium chloride, ammonia, urea, uric acid and creatine and also protein constituents.

FIGS. 9 to 11 in each case illustrate an individual pressure sensor of the two-dimensional array illustrated in FIG. 8, using a pentacene transistor 10. In the first exemplary embodiment 100 illustrated in FIG. 9, the diffusion barrier 30 for water and hydrophilic constituents is applied to the pentacene transistor 10 as first (bottommost) protective layer. This first protective layer 30 includes a hydrophobic material that is deposited on the surface of the pentacene transistors 10 without damaging the sensitive organic semiconductor layer (cf. 5 in FIG. 1). What are suitable for this in particular are paraffins that are a mixture of long-chain, extremely hydrophobic aliphatic hydrocarbons that are commercially available in different chain lengths and thus different melting ranges. For this invention preference is given to paraffins which are solid at room temperature and have a melting range above the maximum use temperature of the components (approximately 80° C.). Paraffins are inexpensive and can also be vaporized without decomposition at relatively low temperatures. Consequently, the application of a paraffin layer can be realized inexpensively. The paraffin film (see FIG. 1) vapour-deposited onto the surface of the active layer 5 affords not only virtually 100% protection against atmospheric humidity (diffusion barrier) but also protects against direct contact with water and hydrophilic constituents. Although paraffins include organic molecules (similarly to organic solvents, for example alcohols, acetone, hexane, petroleum ethers), vapour-deposited paraffin layers do not damage the molecular arrangement of the active organic semiconductor layer 5 and hence the electrical properties thereof. This is due, on the one hand, to the size (length>C17) of the aliphatic hydrocarbons and, on the other hand, to the state of matter of the paraffins, (waxy to solid). In contrast to small organic solvent molecules, diffusion through a layer or a crystal lattice is made significantly more difficult in the case of large molecules. Moreover, the paraffins are solid and thus significantly demobilized. In the exemplary embodiment 100 illustrated in FIG. 9, a hydrophilic polymer layer, preferably polyvinyl alcohol (PVA), serves as second (upper) protective layer 31. The function of the second protective layer consists in the effect as a diffusion barrier with respect to lipophilic constituents, such as talc, protein residues or generally organic constituents.

As is illustrated by the second exemplary embodiment 101 of a fingerprint sensor employing a pentacene transistor 10 as illustrated in FIG. 10, the order of the protective layers is interchanged since both paraffin and PVA can be deposited without any problems on the surface of the transistors without the sensitive organic semiconductor layer 5 being damaged.

In the realization of a fingerprint sensor according to the invention, materials used for the hydrophobic protective layer were particularly those paraffins which are solid at room temperature, for example Aldrich, melting point 73 to 78° C. Inert non-aromatic hydrocarbons which are solid at room temperature and can be vaporized without decomposition, such as adamantane, for example, are also suitable. The hydrophobic protective layer 30 was deposited from the vapour phase as reduced pressure (depending on volatility 10⁻¹ to 10⁻⁴ torr) and elevated temperatures, the substrate having been cooled.

The aqueous formulation of polyvinyl alcohol (1 to 10% in water) proved to be particularly suitable for the hydrophilic protective layer 31 when the latter was applied on a pentacene layer as in the exemplary embodiment 101 in accordance with FIG. 10. An initiator for photochemical crosslinking may optionally be added to such a formulation, the initiator facilitating rapid curing under irradiation with UV light. A corresponding initiator is for example ammonium dichromate (0.01 to 0.1% by weight). The deposition is effected by spin coating, dip coating or spray coating.

FIG. 11 illustrates a third exemplary embodiment 102 of a perspiration-resistant fingerprint sensor using a pentacene transistor 10, in which a perfluorinated material is used as protective layer 32. This type of material makes it possible to use only one protective layer 32, since layers made of perfluorinated compounds, such as perfluorohexadecane, for example, are diffusion barriers both for hydrophobic compounds and for hydrophilic compounds.

In the case of the third exemplary embodiment 102 of the fingerprint sensor according to the invention as illustrated in FIG. 11, all perfluorinated n-alkane derivatives (for example perfluorotetradecane, melting point 103 to 104° C.; perfluorohexadecane, melting point 125-126° C.) and also inert non-aromatic perfluorinated hydrocarbons which are solid at room temperature and which can be vaporized without decomposition (for example perfluoromethyldecalin, melting point 59° C.) are suitable, in principle, for the perfluorinated protective layer 32. The deposition is effected from the vapour phase at reduced pressure (depending on volatility 10⁻¹ to 10⁻⁴ torr) and elevated temperatures (up to 200° C.), in which case the substrate should be cooled.

The same standpoints as were mentioned for the above-described force sensor according to the invention as illustrated in FIG. 1 with regard to a wide range of substrate materials hold true for the substrate materials of the above-described exemplary embodiments, 100, 101, 102 of a fingerprint sensor according to the invention as illustrated in FIGS. 9 to 11.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-16. (canceled)

17. A force sensor comprising:
a substrate; and
an organic field effect transistor applied on the substrate, in which a mechanical force acting on the transistor causes a change in its source-drain voltage or its source-drain current which corresponds to the force and is detected as measurement quantity for the acting force.

18. The force sensor according to claim 17, comprising wherein the organic field effect transistor is a pentacene transistor having an active layer made of pentacene between its source electrode and its drain electrode.

19. The force sensor according to claim 17, comprising wherein the substrate is made of a material from a group consisting of glass, ceramic, plastic, a polymer film, metal film or paper.

20. The force sensor according to claim 19, comprising wherein the substrate comprises a polymer film having a material from a group consisting of polyethylene napthalate, polyethylene terephthalate, polyimide, polycarbonate and/or polyethene ether ketones.

21. The force sensor according to claim 17, comprising wherein the detected measurement quantity is the drain-source voltage of the organic field effect transistor, a constant gate-source voltage and a constant drain current being present at the transistor at the measurement instant.

22. The force sensor according to one of claim 17, comprising wherein the detected measurement quantity is the drain current of the organic field effect transistor, a constant gate-source voltage and a constant drain-source voltage being present at the transistor at the measurement instant.

23. A pressure sensor comprising:
at least one force sensor comprising a substrate, and an organic field effect transistor applied on the substrate, in which a mechanical force acting on the transistor causes a change in its source-drain voltage or its source-drain current which corresponds to the force and is detected as measurement quantity for the acting force; and
where the substrate is configured as a deformable diaphragm and the measurement quantity corresponding to the bending state of the diaphragm.

24. A One- or two-dimensional position sensor for measuring the position of a mechanical force action along a line or within an area using a multiplicity of force sensors comprising:
one or more force sensors comprising a substrate, and an organic field effect transistor applied on the substrate, in which a mechanical force acting on the transistor causes a change in its source-drain voltage or its source-drain current which corresponds to the force and is detected as measurement quantity for the acting force; and
a where the force sensors are arranged at regular distances from one another in a form of a one- or two-dimensional matrix on a common substrate.

25. The sensor according to claim 24, comprising wherein a driving and measuring unit is connected to the drain or source terminals of all the field effect transistors for driving and detecting the position of the force action.

26. The sensor according to claim 25, comprising:
where the organic field effect transistors are arranged in rows and columns; and
a driving and measuring unit is connected to the drain or source terminals of all the columns for the purpose of driving and detecting the column position of the force action and a row decoder is connected or can be connected to the gate terminals of the organic field effect transistors for row-by-row selection and driving of the organic field effect transistors.

27. A fingerprint sensor comprising:
a multiplicity of force sensors according to claim 1 that are arranged on a common substrate at regular distances in the form of a two-dimensional matrix subdivided into rows and columns;
a driving and measuring unit connected to the drain or source terminals of the organic field effect transistors in all columns for the purpose of driving and detecting the column position of the force action; and
a row decoder connected to the gate terminals of the organic field effect transistors of all the rows for row-by-row selection and detection of the position of the force action in the row direction.

28. The fingerprint sensor according to claim 27, comprising:
at least one perspiration-resistant protective layer provided as protection against the ingress of water and organic contaminations above the active layer of the organic field effect transistors.

29. The fingerprint sensor according to claim 28, comprising wherein the protective layer includes a perfluorinated material.

30. The fingerprint sensor according to claims 29, where the perfluorinated material is perfluorohexadecane.

31. The fingerprint sensor according to claim 28, comprising wherein a first protective layer includes a hydrophobic material and a second protective layer includes a hydrophilic polymer which acts as a diffusion barrier against lipophilic contaminants.

32. The fingerprint sensor according to claim 31, comprising wherein the first protective layer covers the second protective layer.

33. The fingerprint sensor according to claim 31, comprising wherein the second protective layer covers the first protective layer.

34. A force sensor comprising:
a substrate; and
means for providing an organic field effect transistor applied on the substrate, in which a mechanical force acting on the transistor means causes a change in its source-drain voltage or its source-drain current which corresponds to the force and is detected as measurement quantity for the acting force.

35. The force sensor according to claim 34, comprising wherein the organic field effect transistor means is a pentacene transistor having an active layer made of pentacene between its source electrode and its drain electrode.

36. The force sensor according to claim 34, comprising wherein the substrate is made of a material from a group consisting of glass, ceramic, plastic, a polymer film, metal film or paper.

37. The force sensor according to claim 34, comprising wherein the substrate comprises a polymer film having a material from a group consisting of polyethylene napthalate, polyethylene terephthalate, polyimide, polycarbonate and/or polyethene ether ketones.
